(19) United States
(12) Patent Application Publication
(10) Pub. No.: US 2025/0299960 A1
(43) Pub. Date: Sep. 25, 2025

(54) INTEGRATED CIRCUIT WITH GLOBAL SILICIDATION

(71) Applicant: Taiwan Semiconductor Manufacturing Company, Ltd., Hsinchu (TW)

(72) Inventors: Chun-Yuan CHEN, Hsinchu (TW); Huan-Chieh SU, Hsinchu (TW); Chih-Hao WANG, Hsinchu (TW); Kuo-Cheng CHIANG, Hsinchu (TW)

(21) Appl. No.: 18/824,670

(22) Filed: Sep. 4, 2024

Related U.S. Application Data
(60) Provisional application No. 63/567,819, filed on Mar. 20, 2024.

(51) Int. Cl. H01L 21/285; H01L 29/06; H01L 29/423; H01L 29/45; H01L 29/66; H01L 29/775; H01L 29/786

(52) U.S. Cl. CPC H01L 21/28518; H10D 30/014; H10D 30/43; H10D 30/6735; H10D 30/6757; H10D 62/121; H10D 62/83; H10D 64/62

(57) ABSTRACT

A method of forming an integrated circuit includes forming a source/drain region coupled to a plurality of channels of a transistor and forming a silicide in contact with the source/drain region. The method includes depositing a first metal layer of a source/drain contact of the transistor on the silicide with a first deposition process and patterning the silicide by performing an etching process using the first metal layer as a mask. A second metal layer of the source/drain contact is then deposited on the first metal layer. The first metal layer is laterally wider than the second metal layer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-22 are cross-sectional views, top views, and perspective views of an integrated circuit at various stages of processing, in accordance with some embodiments.

FIG. 23 is a flow diagram of a method for operating an integrated circuit, in accordance with some embodiments.

FIG. 24 is a flow diagram of a method for operating an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

Embodiments of the present disclosure provide an integrated circuit including transistors having source/drain contacts with improved electrical characteristics. Silicide is provided between the semiconductor source/drain regions and source/drain contacts. A first source/drain contact metal is formed on the silicide and the silicide is patterned in the presence of the first source/drain contact metal. A second source/drain contact metal is then deposited on the first source/drain contact metal. The silicide has a relatively large area in order to help reduce the resistance between the source/drain contacts and the source/drain regions. Because the resistance is reduced by increasing silicide area, the critical dimension of the source/drain contact can be decreased. This further results in increased scalability of source/drain contacts and a decrease in the capacitance between the source/drain contacts and gate metals. This results in transistors having improved processing speeds, reduced power consumption, and reduced area consumption. This further results in better functioning integrated circuits.

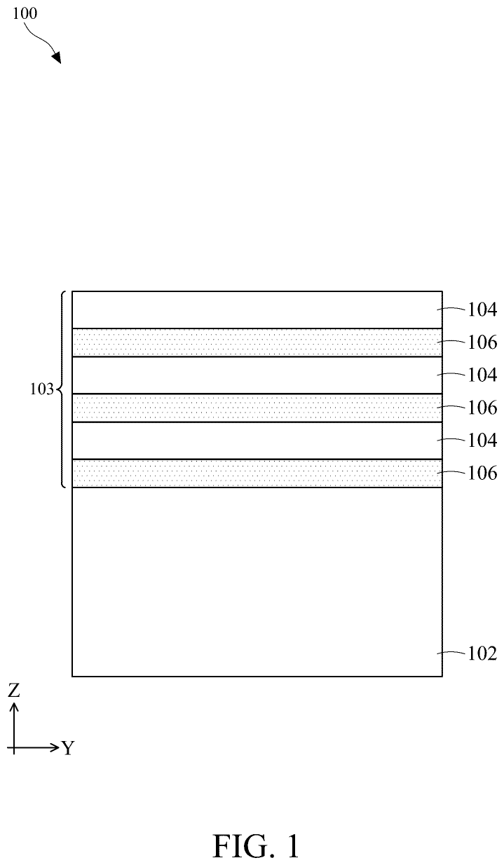

FIGS. 1-22 are cross-sectional views, top views, and perspective views of an integrated circuit 100 fabricated in accordance with some embodiments of the present disclosure. The fabrication process results in a plurality of transistors 101, as will be described in further detail below.

FIG. 1 is a perspective view of the integrated circuit 100 at an intermediate state of processing. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, Three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

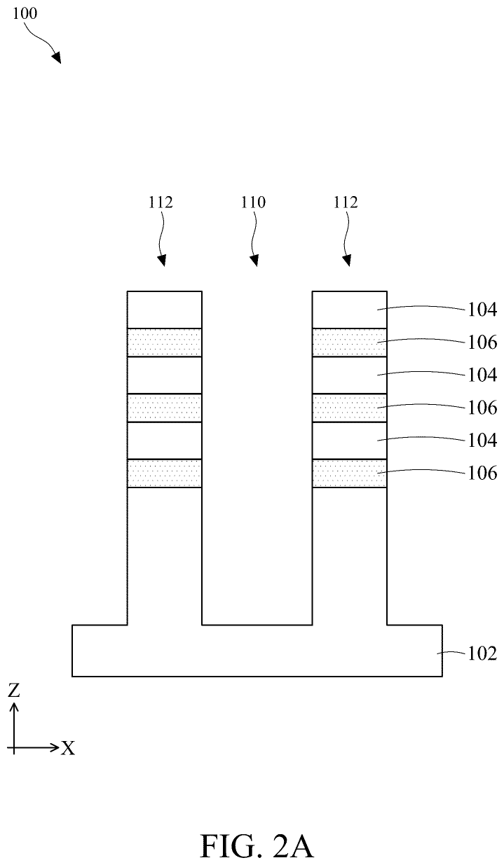

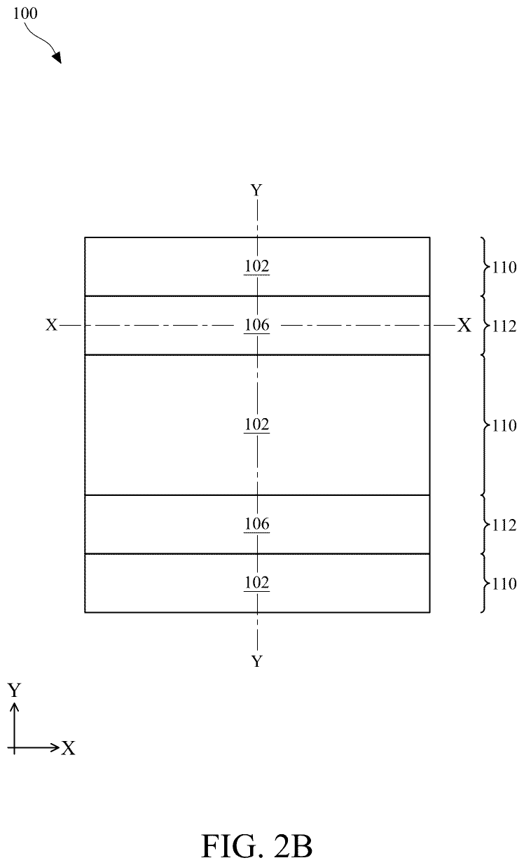

In FIG. 2A, trenches 110 have been formed in the stack 103 and in the substrate 102. Though not shown in FIG. 1, a hard mask layer is first formed and patterned on the stack 103. The trenches 110 can be formed with an anisotropic etching process that etches in the downward direction in the presence of the patterned hard mask. The etching process defines semiconductor fins 112 by forming trenches 110 through the sacrificial semiconductor layers 106, the semiconductor layers 104, and the substrate 102.

FIG. 2B is a top view of the integrated circuit 100 of FIG. 2A, in accordance with some embodiments. The top view of FIG. 2B illustrates the fins 112 extending in the X direction and the trenches 110 between the fins 112. The substrate 102 is visible in the trenches 110. The top-most semiconductor layer 106 is visible atop the fins 112. As set forth previously, in practice, a hard mask layer may be positioned on top of the top-most semiconductor layer 106. FIG. 2B also illustrates cut-lines X and Y. A cross-sectional view along the cut lines Y may be referred to as a “Y-view”. A cross-sectional view along the cut lines X may be referred to as a “X-view”.

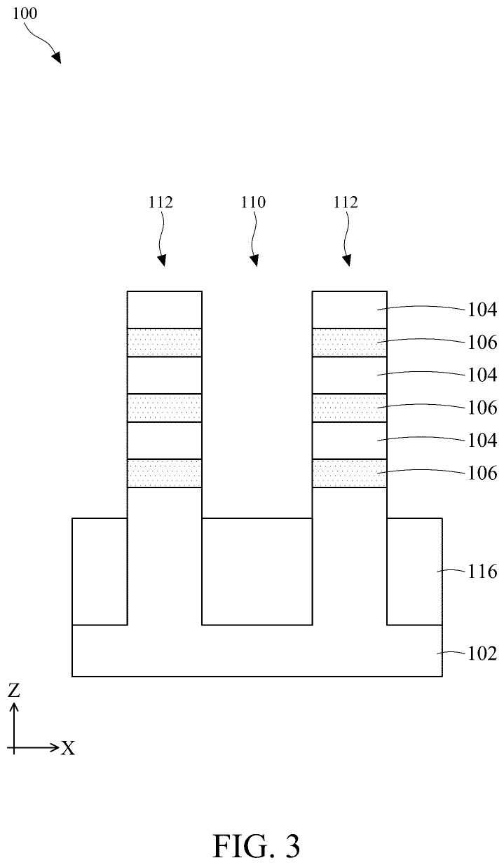

FIG. 3 is a cross-sectional Y-view, in accordance with some embodiments. In FIG. 3, shallow trench isolation regions 116 have been formed by depositing a dielectric material in the trenches 110 between fins 112. The shallow trench isolation regions 116 may be deposited by chemical vapor deposition (CVD), atomic layer deposition (ALD), physical vapor deposition (PVD), or other suitable deposition processes. In an exemplary embodiment, the shallow trench isolation regions includes silicon oxide. However, the shallow trench isolation regions can include SiN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

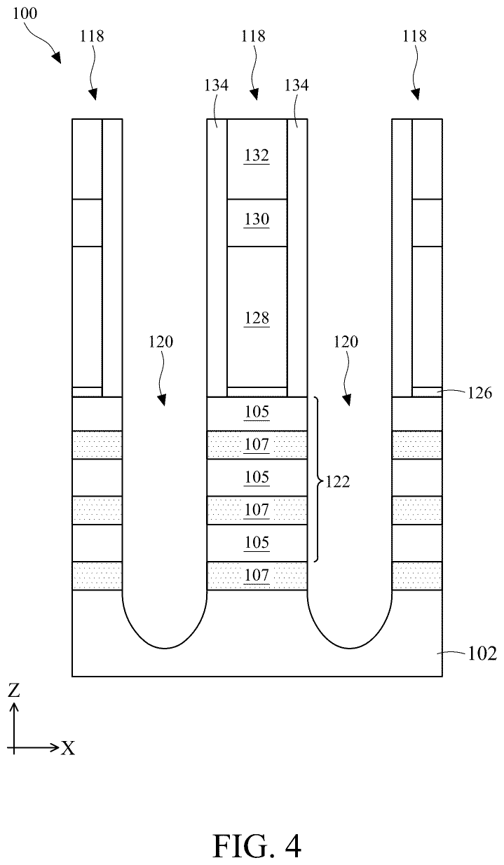

FIG. 4 is an X-view of the integrated circuit 100, in accordance with some embodiments. In FIG. 4, sacrificial gate structures 118 have been formed over the fins 112. The sacrificial gate structures 118 extend in the Y direction, perpendicular to the fins 112. Each sacrificial gate structure 118 crosses multiple fins 112. The sacrificial gate structures 118 are also formed in the trenches 110.

The sacrificial gate structures 118 include a dielectric layer 126. In an exemplary embodiment, the dielectric layer 126 includes silicon oxide. However, alternatively, the dielectric layer 126 can include SiN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material.

The sacrificial gate structures 118 include a dielectric layer 130 on the sacrificial gate layer 128 and a dielectric layer 132 of the dielectric layer 130. The dielectric layers 130 and 132 may correspond to first and second mask layers. The dielectric layer 130 can include silicon nitride, silicon oxynitride, or other suitable dielectric materials. The dielectric layer 130 can include silicon nitride, silicon oxynitride or other suitable dielectric materials. The dielectric layers 130 and 132 are different materials from each other and can be deposited using CVD, ALD, PVD, or other suitable deposition processes. Other materials and deposition processes can be utilized for the dielectric layers 130 and 132 without departing from the scope of the present disclosure.

Gate spacer layers 134 have been formed on the sidewalls of the layers 126, 128, 130, and 132. The gate spacer layers 134 may also be formed on other exposed surfaces of the integrated circuit. The gate spacer layer 134 can be formed by PVD, CVD, ALD, or other suitable deposition processes. Following formation of the gate spacer layer 134, horizontal portions (e.g., in the X-Y plane) of the gate spacer layer 134 may be removed by an anisotropic etching process, thereby exposing upper surfaces of the fins 112 and the dielectric layer 134. After patterning of the gate spacer layers, vertically thicker portions of the gate spacer layers 134 remain, such as the portion shown in FIG. 4. The gate spacer layers 134 can include one or more of SiO, SiN, SiON, SiCN, SiOCN, SiOC, or other suitable dielectric materials.

After patterning of the gate spacer layers 134, an etching process is performed to form source/drain trenches 120 in the fins 112. One or more etching processes are performed to form the source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 120 results in formation of stacks of channels 105. In particular, the portions of the semiconductor layers 104 after formation of the source/drain trenches 120 now correspond to channels of a transistor. Formation of the source/drain trenches 120 also results in formation of a plurality of sacrificial semiconductor nanostructures 107 from the sacrificial semiconductor layers 106.

A large number of source/drain trenches 120 are formed in the fins 112. A stack 122 of channels 105 is positioned between each source/drain layer. Each stack 122 of channels 105 corresponds to the stacked channels 105 of a transistor.

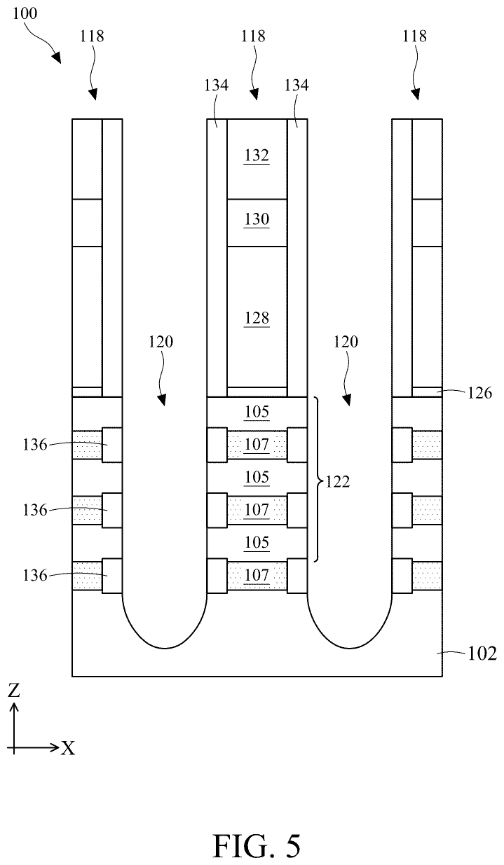

In FIG. 5, inner spacers 136 have been formed. A selective etching process is performed to recess exposed end portions of the sacrificial semiconductor nanostructures 107 without substantially etching the sacrificial semiconductor nanostructures 107. Next, the inner spacers 136 are formed by depositing a dielectric material to fill the recesses between the channels 105 formed by the previous selective etching process of the sacrificial semiconductor nanostructures 107. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like. An etching process, such as an anisotropic etching process, is performed to remove portions of the inner spacer 136 disposed outside the recesses in the sacrificial semiconductor nanostructures 107. The remaining portions of the dielectric layer correspond to the inner spacers 136 shown in FIG. 5.

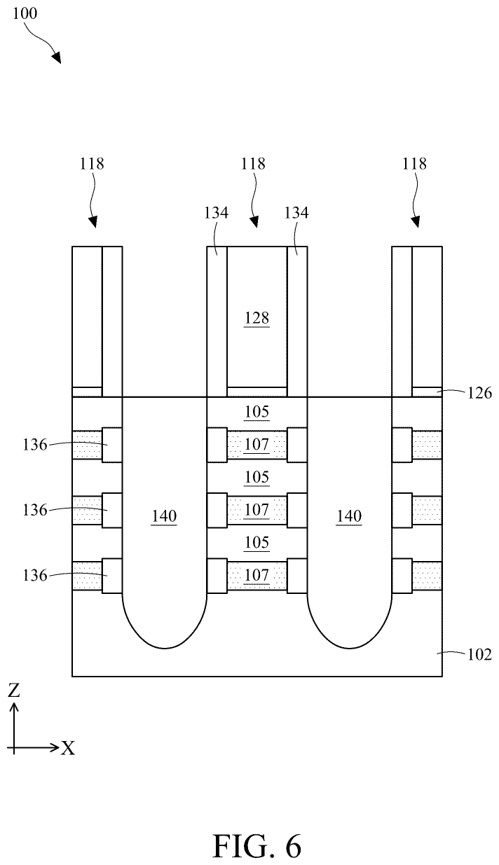

In FIG. 6 source/drain regions 140 have been formed. In the illustrated embodiment, the source/drain regions 140 are epitaxially grown from the channels 105. The source/drain regions 140 are grown on exposed portions of the fins 112 and contact the channels 105. For each stack 122 of channels 105, there are two source/drain regions 140. Some stacks 122 of channels 105 may share a source/drain 140 with a stack 122 of channels 105 that is adjacent in the X direction.

Though not shown, dielectric support elements corresponding to remnants of the gate spacer layers 134 on the trench isolation regions 116 may laterally confine the growth of source/drain regions 140. In some embodiments, the source/drain regions 140 exert stress in the respective channels 105, thereby improving performance. The source/drain regions 140 are formed such that each sacrificial gate structure 118 is disposed between respective neighboring pairs of the source/drain regions 140. In some embodiments, the spacer layer 134 and the inner spacers 136 separate the source/drain regions 140 from the sacrificial gate layer 128 by an appropriate lateral distance (e.g., in the X-axis direction) to prevent electrical bridging to subsequently formed gates of the resulting device.

The source/drain regions 140 may include any acceptable material, such as appropriate for n-type or p-type devices. For n-type devices, the source/drain regions 140 include materials exerting a tensile strain in the channel regions, such as silicon, SiC, SiCP, SiP, or the like, in some embodiments. When p-type devices are formed, the source/drain regions 140 include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

The source/drain regions 140 may be implanted with dopants followed by an annealing process. The source/drain regions 140 may have an impurity concentration of between about 10¹⁹ cm⁻³ and about 10²¹ cm⁻. N-type and/or p-type impurities for source/drain regions 140 may be any of the impurities previously discussed. In some embodiments, the source/drain regions 140 are in situ doped during growth.

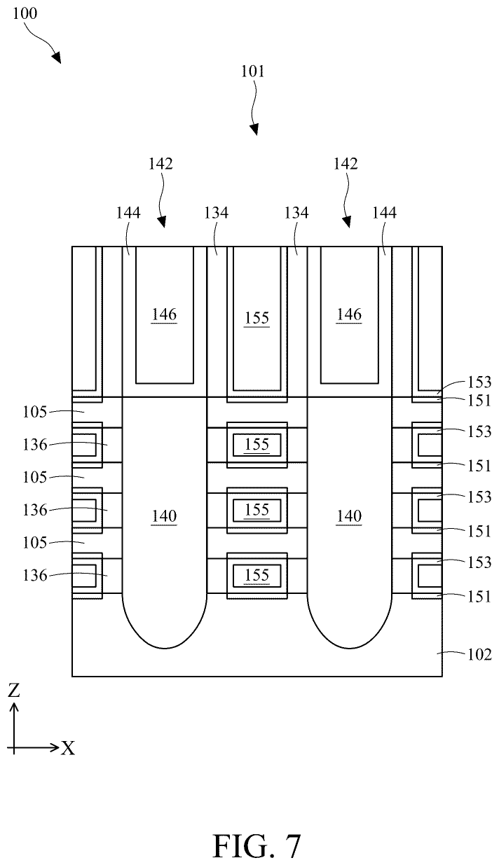

FIG. 7 is an X-view of the integrated circuit 100, in accordance with some embodiments. In FIG. 7, a dielectric layer 144 and an interlayer dielectric (ILD) 146 have been formed above the source/drain regions. The dielectric layer 144 may correspond to an etch stop layer (ESL). The dielectric layer 144 can include a thin dielectric layer can formally deposited on exposed surfaces of the source/drain regions 140 and on other exposed surfaces. The dielectric layer 144 can include SiN, SiC, SiOC, SiOCN, SiON, or other suitable dielectric materials. The dielectric 144 can be deposited by CVD, ALD, PVD, or other suitable deposition processes.

The dielectric layer 146 covers the dielectric 144. The dielectric layer 146 can include SiO, SiON, SiN, SiC, SiOC, SiOCN, SiON, or other suitable dielectric materials. The dielectric layer 146 can be deposited by CVD, ALD, PVD, or other suitable deposition processes.

In FIG. 7, the sacrificial gate structures 118 have been removed from between the gate spacer layers 134. In particular, the dielectric layer 126 and the sacrificial gate layer 128 have been entirely removed from between the gate spacer layers 134.

In some embodiments, the sacrificial gate layer 128 is removed by an anisotropic dry etch process. For example, the etching process may include a dry etch process using reaction gases that selectively etch the sacrificial gate layer 128 without etching the spacer layer 134. The dielectric layer 126, when present, may be used as an etch stop layer when the sacrificial gate layer 128 is etched. The dielectric layer 126 may then be removed after the removal of the sacrificial gate layer 128.

Removal of the sacrificial gate layer 128 and the dielectric layer 126 results in the formation of a void between the gate spacer layers 134 above the channels 105. As will be set forth in more detail below, an upper portion of a gate metal or gate electrode will be formed in the void. Accordingly, the sacrificial gate layer 128 is sacrificial in the sense that the upper portion of the gate metal will eventually be formed in its place.

In FIG. 7, channels 105 are released by removal of the sacrificial semiconductor nanostructures 107. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 107 are removed and the channels 105 are patterned to form channel regions of both PFETs and NFETs. Removal of the sacrificial semiconductor nanostructures 107 results in the formation of voids between the channels 105.

After release of the channels 105, an interfacial gate dielectric layer 151 has been deposited. The interfacial gate dielectric layer 151 is deposited on all exposed surfaces of the channels 105. The interfacial gate dielectric layer 151 is wrapped around the channels 105. The interfacial gate dielectric layer 151 can include a dielectric material such as silicon oxide, silicon nitride, or other suitable dielectric materials. The interfacial gate dielectric layer 151 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 151 can be formed by a thermal oxidation process, a chemical vapor deposition (CVD) process, or an atomic layer deposition (ALD) process. The interfacial gate dielectric layer 151 can have a thickness between 0.5 nm and 2 nm. Other materials, deposition processes, and thicknesses can be utilized for the interfacial gate dielectric layer 151 without departing from the scope of the present disclosure.

A high-K dielectric layer 153 has been deposited. The high-K dielectric layer 153 is deposited in a conformal deposition process. The conformal deposition process deposits the high-K dielectric layer 153 on the interfacial gate dielectric layer 151, on the hard mask structure 109, on the substrate 102, on the trench isolation regions 116, and on the gate spacer layers 134. The high-K gate dielectric layer 153 is wrapped around the channels 105. The high-K gate dielectric layer 153 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 153 may be formed by CVD, ALD, or any suitable method. Other thicknesses, deposition processes, and materials can be utilized for the high-K dielectric layer 153 without departing from the scope of the present disclosure.

A gate metal 155 has been deposited. The gate metal 155 is deposited on all exposed surfaces of the high-K dielectric layer 153. The gate metal 155 is wrapped around the channels 105. Although the gate metal 155 is shown as a single layer in FIG. 7, in practice, the gate metal 155 can include one or more conductive liner layers, work function layers, and gate fill layers that collectively make up the gate metal. The gate metal can include one or more of Ti, TiN, Ta, TaN, Al, Cu, Co, Ru, W, Au, or other suitable conductive materials. The gate metal 155 can be deposited by PVD, ALD, or CVD. Other configurations, materials, and deposition processes can be utilized for the gate metal 155 without departing from the scope of the present disclosure. The gate metal 155 acts as a gate electrode surrounding the channels 105.

At the stage of processing shown in FIG. 7, the transistors 101 are substantially complete, apart from formation of source/drain contacts and cut metal gate structures, as described in more detail below. Each transistor 101 includes a stack 122 of channels 105 extending between the source/drain regions 140 and acting as stacked channels of the transistor 101.

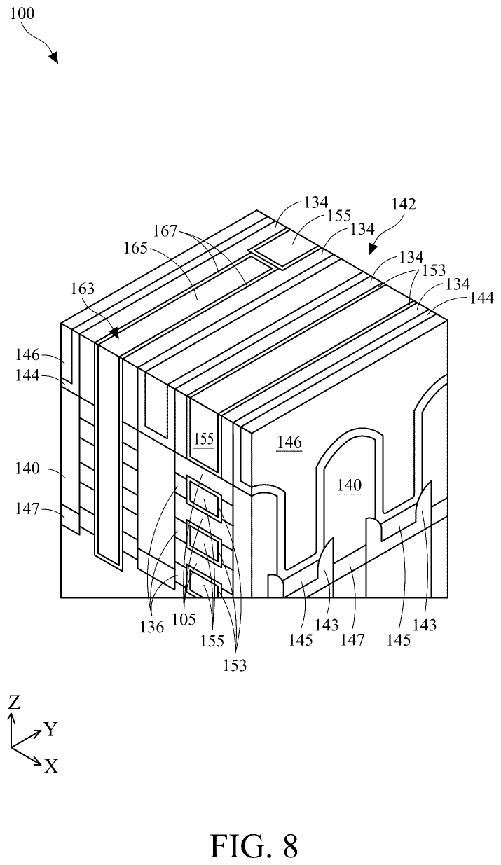

FIG. 8 is a perspective view of the integrated circuit 100, in accordance with some embodiments. A CMP process has been performed to reduce the height of the various surface features shown in FIG. 7.

In FIG. 8, isolation structures 163 have been formed in place of the gate metal 155 at some locations. The isolation structures 163 include a dielectric layer 165 and a dielectric layer 167. The dielectric layer 165 can include SiO, SiON, SiN, SiC, SiOC, SiOCN, SiON, or other suitable dielectric layer. The dielectric layer 167 is a dielectric liner layer positioned on sidewalls of the gate spacer layers 134. The dielectric layer 167 can include SiO, SiON, SiN, SiC, SiOC, SiOCN, SiON, or other suitable dielectric materials. The dielectric layers 165 and 167 can be deposited by CVD, ALD, PVD, or other suitable deposition processes. In one example, the dielectric layer 165 includes silicon oxide and the dielectric layer 167 includes silicon nitride. In some embodiments, the isolation structures 163 can be cut-poly on OD end (CPODE) structures.

FIG. 8 also illustrates bottom dielectric structures 147 below the source/drain regions 140. The bottom dielectric structures 147 can be formed prior to formation of the source/drain regions 140. The bottom dielectric structures 147 can include SiO, SiON, SiN, SiC, SiOC, SiOCN, SiON, or other suitable dielectric materials. The bottom dielectric structures 147 can be deposited by CVD, ALD, PVD, or other suitable deposition processes.

FIG. 8 also illustrates a dielectric layer 143 formed on a top surface of the shallow trench isolation regions 116 at selected locations. In some embodiments, the dielectric layer 143 is a remnant of the dielectric layer that forms the gate spacer layers 134. Accordingly, in some embodiments, the dielectric layer 143 is a same material as the gate spacer layers 134. FIG. 8 also illustrates a dielectric layer 145 positioned on the dielectric layer 143. The dielectric layer 145 can include silicon oxide or other suitable dielectric materials. The dielectric layer 144 can be formed on a top surface of the dielectric layer 145 and in contact with portions of the dielectric layer 143.

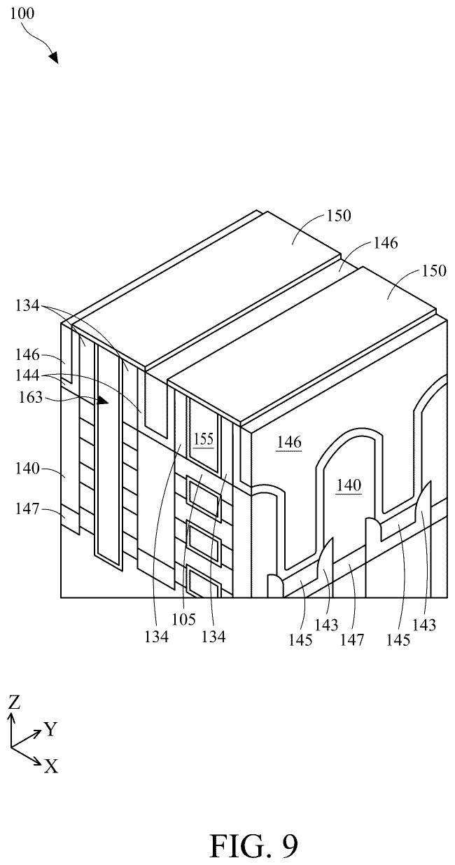

In FIG. 9, a hard mask layer 150 has been deposited. The hard mask layer 150 is formed by selectively depositing a hard mask material on the gate metal 155, the gate spacer layers 134, the dielectric layer 144, and the polysilicon layer 165. In some embodiments, the hard mask layer 150 does not grow on the interlevel dielectric layer 146 because the hard mask layer 150 selectively grows on the gate metal 155 and layers that include nitrogen, whereas in some embodiments the interlevel dielectric layer 146 is silicon oxide. In some embodiments, the hard mask layer 150 includes pure titanium deposited by ALD or other suitable deposition processes. In some cases, a small amount of the hard mask layer 150 may grow on the interlevel dielectric layer 146. In these cases, an etching process including exposing the integrated circuit 100 to a diluted hydrofluoric acid (DHF) can remove the small amount of hard mask material from the interlevel dielectric layer 146.

In some embodiments, the hard mask layer 150 is formed using conventional photolithography processes. In particular, a hard mask material may be deposited via CVD, ALD, or other suitable deposition processes. Photolithography may then be performed to pattern the hard mask layer 150 as shown in FIG. 9.

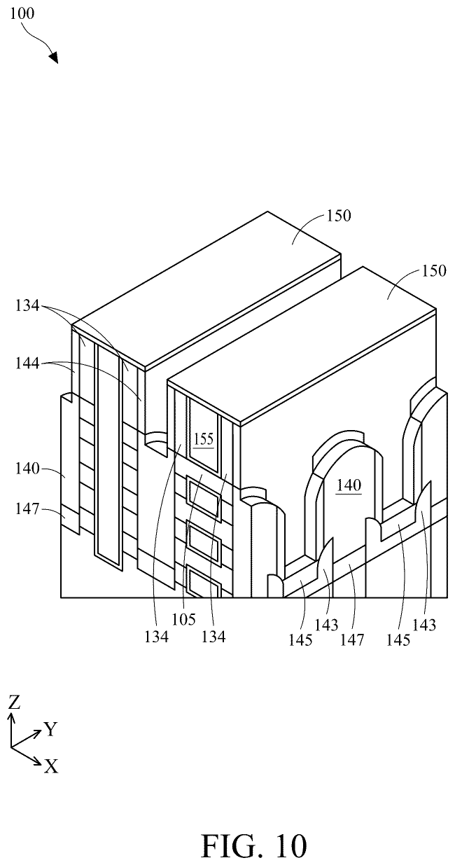

FIG. 10 is a perspective view of the integrated circuit 100, in accordance with some embodiments. In FIG. 10, and etching processes been performed in the presence of the hard mask layer 150. The etching process removes the interlevel dielectric layer 146 and the bottom portion of the dielectric layer 144, thereby exposing a top surface of the source/drain regions 140. After the etching process, the dielectric layer 144 remains on sidewalls of the gate spacer layers 134 directly below the hard mask layer 150. Vertically thicker portions of the dielectric layer 144 also remain outside of the coverage of the hard mask layer 150. For example, while the dielectric layer 144 has been removed from the top surfaces of the source/drain region 140 and the dielectric layer 145, the vertically thicker portions of the dielectric layer 144 remain on sidewalls of the source/drain regions 140 above the dielectric layer 145.

The etching process partially recesses the top surface of the source/drain region 140 adjacent to a highest channel 105 of the transistor 101. This results in a U-shaped cavity in the top surface of the source/drain region 140 that certain locations.

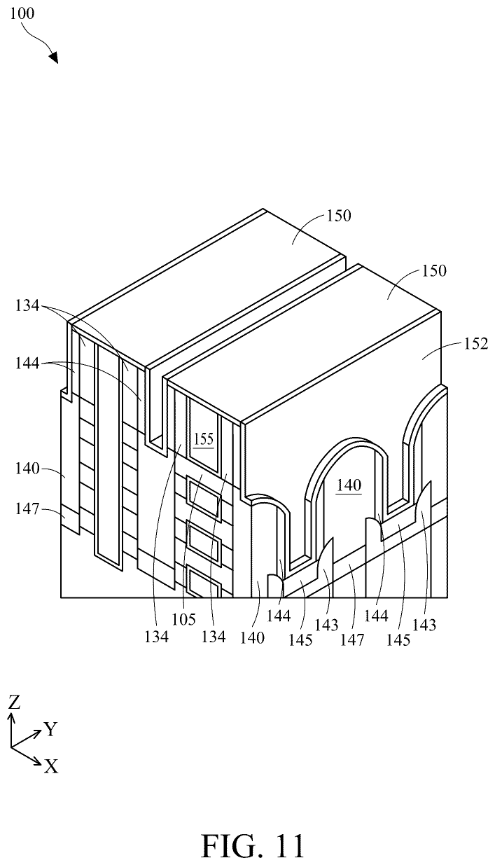

FIG. 11 is a perspective view of the integrated circuit 100, in accordance with some embodiments. In FIG. 11, a silicide layer 152 has been formed. The silicide layer 152 can be formed by depositing a metal layer on the source/drain regions 140 and on other exposed surfaces. The metal layer is selected based on the type of silicide to be formed. The metal layer can include Ni, Ti, Al, Sb, Ru, Mo, Zr, Nb, Sc, Y, Rh, Ir, W, or other suitable metal layers. After deposition of the metal layer, a thermal annealing process is performed. The thermal annealing process results in the formation of the silicide 152. The silicide corresponds to a combination of silicon from the source/drain regions 140 and the metal of the metal layer. As can be seen in FIG. 11, the silicide 152 also forms on the dielectric layers 144 and 145 due to the presence of silicon and the dielectric layers 144 and 145. The silicide may have a thickness between 0.2 nm and 10 nm, though other thicknesses can be utilized without departing from the scope of the present disclosure.

In some embodiments, the dopant implantation process is performed prior to deposition of the metal layer for the silicide. More particularly, for P-type transistors, P-type dopants can be deposited in the upper portion of the source/drain regions 140 prior to deposition of the metal layer for the silicide. This is beneficial in reducing the interface resistance.

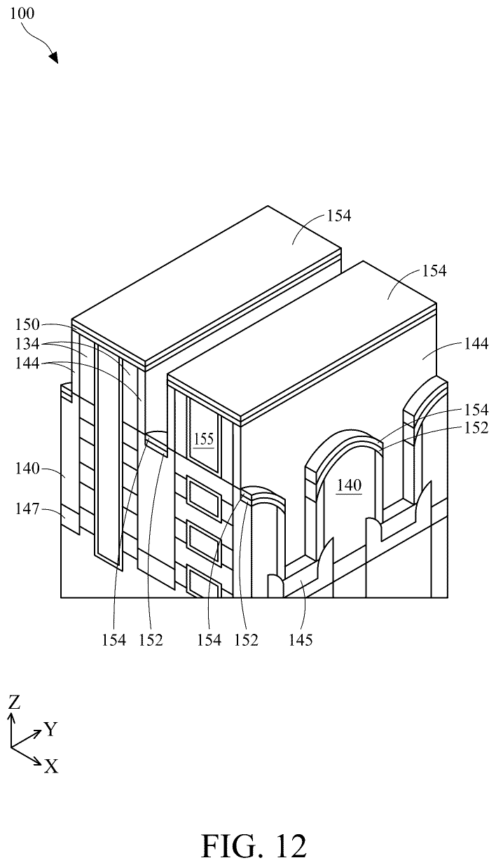

FIG. 12 is a perspective view of the integrated circuit 100, in accordance with some embodiments. In FIG. 12, a metal layer 154 has been deposited. The metal layer 154 can be deposited by PVD with a high directionality such that the metal layer 154 primarily grows on the horizontal surfaces with little or no growth on vertical surfaces. The result is that the metal layer 154 is formed on the hard mask layer 150 and on the portion of the silicide layer 152 that has been formed on the source/drain regions 140.

In some embodiments, after deposition of the metal layer 154, and etching process is performed. The etching process removes the silicide layer 152 from all locations not covered by the metal layer 154. The result is that the silicide layer 152 is removed from the dielectric layers 144 and 145. The silicide layer 152 remains on the source/drain regions 140. The metal layer 154 may be termed a metal cap layer because the metal layer 154 acts as a cap or mask that protects the silicide 152 below the metal layer 154.

In some embodiments, the metal layer 154 is a very low resistance metal. In some embodiments, the low resistance metal includes tungsten, ruthenium, molybdenum, copper, iridium, aluminum, or other suitable metal materials. The metal layer 154 may have a thickness between 0 nm and 2 nm. The metal layer 154 may be thinner at the edges of the silicide 152 based on deposition properties of PVD processes.

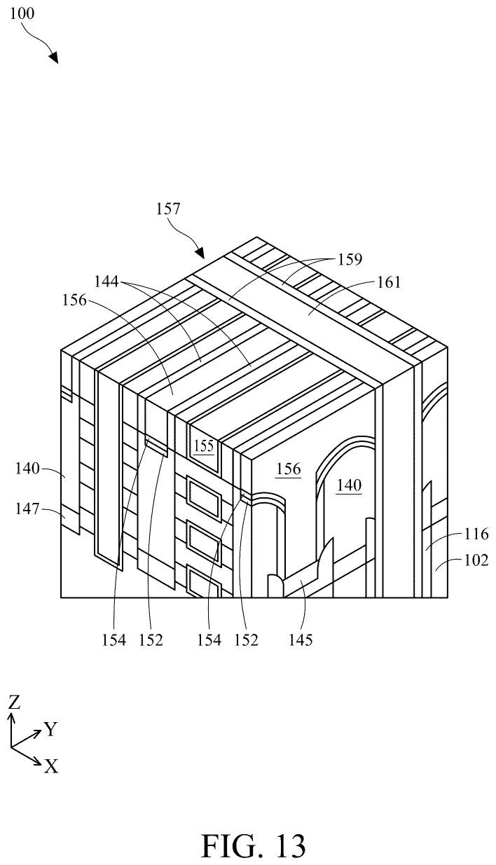

FIG. 13 is a perspective view of the integrated circuit 100, in accordance with some embodiments. In FIG. 13, an interlevel dielectric layer 156 has been deposited. In one example, the interlevel dielectric layer 156 include silicon oxide. However, other dielectric materials can be utilized without departing from the scope of the present disclosure. The interlevel dielectric layer 156 is positioned on the metal layer 154 above the source/drain regions 140. The interlevel dielectric layer 156 is also in direct contact with the dielectric layer 145 and on sidewalls of the dielectric layer 144.

After formation of the interlevel dielectric layer 156, a CMP process has been performed. The CMP process removes the hard mask layer 150 and the metal layer 154 that was positioned on the hard mask layer 150.

In FIG. 13, gate isolation structures 157 have been formed. The gate isolation structures 157 may also be termed “cut metal gate” (CMG) structures. The gate isolation structures 157 electrically isolate the gate electrodes of transistors 101 adjacent to each other in the Y direction. The gate isolation structures 157 are formed by forming a trench extending in the X direction. The trench extends entirely through the gate metal 155 so that the gate metals 155 of transistors adjacent to each other in the Y direction are electrically isolated from each other. The trench extends downward through the dielectric layer 143 into trench isolation regions 116 and may even extends into the substrate 102, in some embodiments. The dielectric materials of the deposited in the trench.

The gate isolation structures 157 include a dielectric layer 159. The dielectric layer 159 corresponds to a dielectric liner layer and can include SiO, SiON, SiN, SiC, SiOC, SiOCN, SiON, or other suitable dielectric materials. The dielectric layer 159 can be deposited by CVD, ALD, PVD, or other suitable deposition processes.

The gate isolation structures include a dielectric layer 161. The dielectric layer 161 fills the gaps between the adjacent portions of the dielectric liner layer 159. The dielectric layer 161 can include SiO, SiON, SiN, SiC, SiOC, SiOCN, SiON, or other suitable dielectric materials. The dielectric layer 161 can be deposited by CVD, ALD, PVD, or other suitable deposition processes. In an exemplary embodiment, the dielectric layer 159 includes silicon nitride and the dielectric layer 161 include silicon oxide.

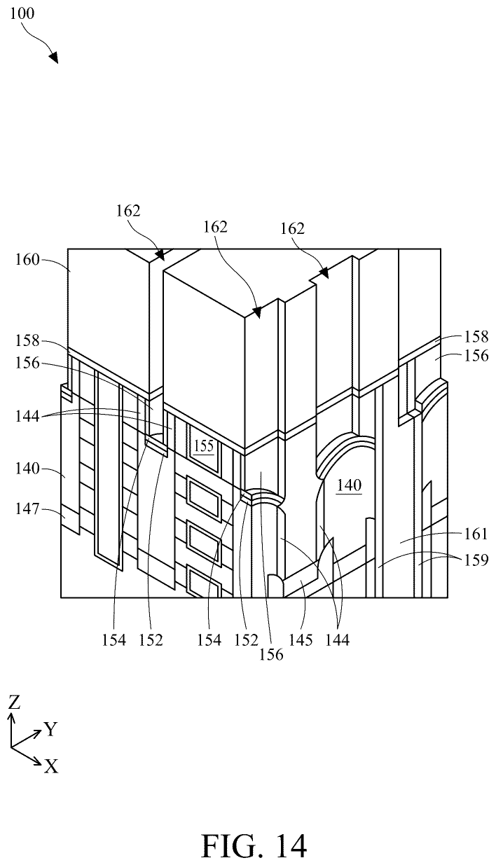

FIG. 14 is a perspective view of the integrated circuit 100, in accordance with some embodiments. In FIG. 14, a dielectric layer 158 has been deposited on the top surface of the integrated circuit 100 such that initially the dielectric layer 158 covers the entirety of the top surface shown in FIG. 13. The dielectric layer 158 may correspond to an etch stop layer (ESL) and may include SiN, SiC, SiOC, SiOCN, SiON, or other suitable dielectric materials. The dielectric 158 can be deposited by CVD, ALD, PVD, or other suitable deposition processes.

An interlevel dielectric layer 160 has been deposited on the dielectric layer 158. The dielectric layer 160 covers the dielectric layer 158. The dielectric layer 160 can include SiO, SiON, SiN, SiC, SiOC, SiOCN, SiON, or other suitable dielectric materials. The dielectric layer 160 can be deposited by CVD, ALD, PVD, or other suitable deposition processes.

After deposition of the dielectric layers 158 and 160, trenches 162 have been formed. The trenches 162 correspond to source/drain contacts trenches extending through the dielectric layers 160, 158, and 156 and exposing the metal layer 154. Accordingly, the etching process stops on the metal layer 154. In some embodiments, portions of the dielectric layer 156 remains on sidewalls of the dielectric layer 144 above the metal layer 154.

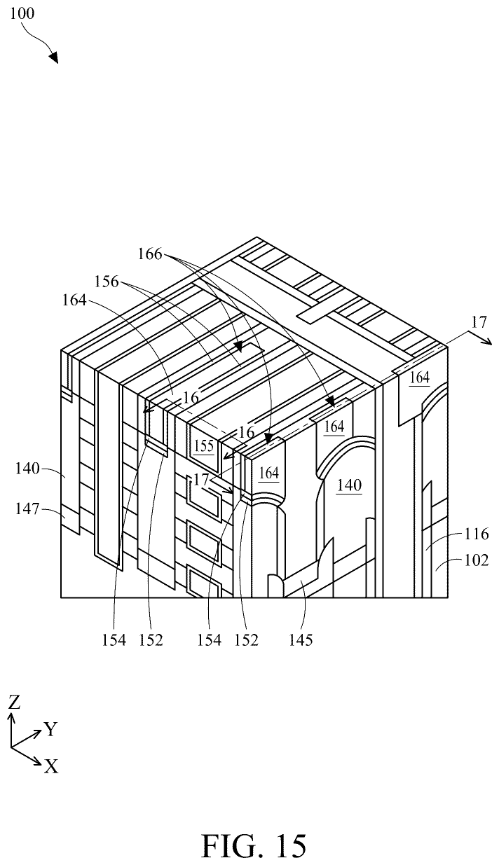

FIG. 15 is a perspective view of the integrated circuit 100, in accordance with some embodiments. In FIG. 15, a metal layer 164 has been formed in the trenches 162. The metal layer 164 is in direct contact with the top surface of the metal layer 154 and with sidewalls of the dielectric layer 156. The metal layer 164 is a low resistance metal such as W, Ru, Mo, Cu, Ir, Al, or other suitable metal materials.

In some embodiments, the metal layer 164 is a same material as the metal layer 154. This results in a homogenous interface between the metal layer 154 and the metal layer 164. This reduces interference contact resistance. In some embodiments, the metal layer 164 is a different metal than the metal layer 154.

After formation of the metal layer 164, a CMP process is performed. The CMP process reduces the height of the metal layer 164 and results in formation of source/drain contacts 166. More particularly, the metal layers 154 and 164 collectively form source/drain contacts 166. Each source/drain contact 166 is electrically connected to a corresponding source/drain region 140, with the silicide 152 positioned between the source/drain contact 166 and the source/drain region 140.

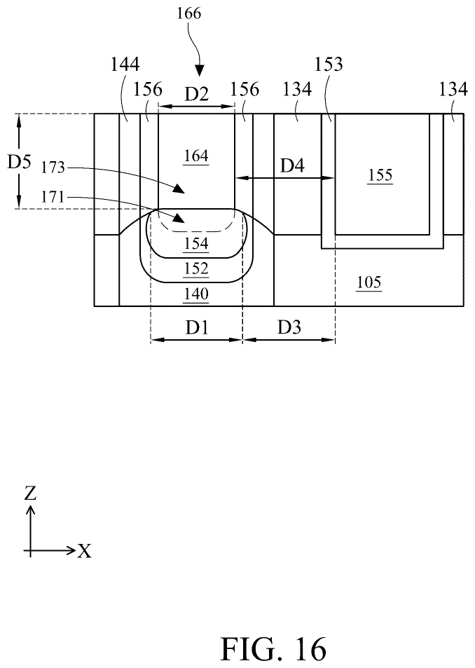

FIG. 16 is a cross-sectional view of the integrated circuit 100 of FIG. 15 taken along cut lines 16, in accordance with some embodiments. FIG. 16 illustrates an interface between the metal layers 154 and 164. However, as described previously, in some embodiments the metal layers 154 and 164 are a same material, resulting in no apparent interface or boundary between the metal layers 154 and 164.

In FIG. 16, the source/drain contact 166 includes a lower region 171 and an upper region 173. The lower region 171 corresponds to the portion of the source/drain contact 166 that is lower than a bottom of the dielectric layer 156 and includes the metal layer 154 and a lower portion of the metal layer 164. The upper region 173 corresponds to the portion of the metal layer 164 that is higher than a bottom surface of the dielectric layer 156.

In some embodiments, the lower region 171 has a width dimension D1 in the X direction. The upper region 173 has a width dimension D2 that is less than the width dimension D1. In some embodiments, the dimension D1 is between 5 nm and 30 nm. In some embodiments, the dimension D2 is between 3 nm and 20 nm. Other values of D1 and D2 can be utilized without departing from the scope of the present disclosure.

In some embodiments, the lower region 171 is separated from the gate metal 155 in the X direction by a dimension D3. The upper region 173 is separated from the gate metal 155 in the X direction by a dimension D4. The dimension D4 is larger than the dimension D3. Because the upper portion 173 and spaced further apart from the gate metal 155, the overall capacitance between the source/drain contact 166 and the gate metal 155 (also termed gate-to-drain capacitance) is greatly reduced. Furthermore, this results in a critical dimension of the source/drain contacts 166 that is greatly reduced. In some embodiments, the critical dimension is between 2 nm and 4 nm smaller than other possible solutions. In some embodiments, the distance between the upper region 164 and the gate metal 155 is between 1 nm and 2 nm greater than other possible solutions. Furthermore, the resistance of the source/drain contact 166 is reduced based on the greater silicide contact area and the self-aligned nature of the silicide.

In some embodiments, the top level of the metal layer 154 is higher than a top surface of the highest channel 105. Alternatively, in some embodiments, the top level of the metal layer 154 may be lower than a top surface of the highest channel 105. In some embodiments, a top surface of the metal layer 154 may be between 5 nm below and 20 nm above the top surface of the topmost channel 105. In some embodiments, the upper region 173 of the source/drain contact 166 has a height dimension D5 between 0 nm and 20 nm, depending on a top level of the metal layer 154. In some embodiments, the upper region 173 may be entirely removed and the CMP process.

In some embodiments, the trench 162 can have an overlay shift between 0 nm and 6 nm in the X direction during formation. In other words, due to the wide lower region 171, there is greater flexibility in alignment constraints in formation of the trench 162 in which the metal layer 164 is deposited. Accordingly, alignment constraints may be greatly relaxed.

In some embodiments, though not shown in FIG. 16, a portion of the silicide layer 152 may remain on the sidewall of the dielectric layer 144. However, in practice, the sidewall silicide will typically be entirely removed during the etching process performed in the presence of the metal layer 154.

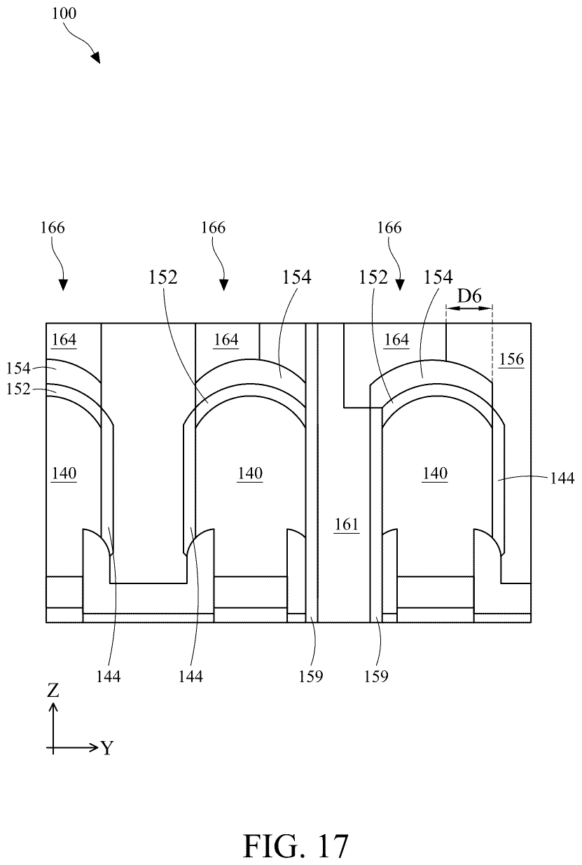

FIG. 17 is a cross-sectional view of the integrated circuit 100 of FIG. 15, taken along cut lines 17, in accordance with some embodiments. As can be seen in FIG. 17, the metal layer 154 has a larger contact area on the silicide 152 than is the contact area between the metal layer 154 and the metal layer 164. The large silicide contact area results in a smaller contact resistance. This is based, in part, on the silicide interface having a greater impact on resistance. If the silicide interface is good, then the upper region 173 can have reduced dimensions without negatively impacting the overall resistance.

FIG. 17 also illustrates that the metal layer 164 is intentionally formed smaller in the Y direction to enable scaling down. Furthermore, the right edge of the metal layer 164 is shifted laterally with respect to the right edge of the metal layer 154 by a dimension D6. This helps reduce the capacitance between adjacent source/drain contacts 166. The dimension D6 may be between 0 nm and 30 nm, though other values may be utilized without departing from the scope of the present disclosure.

As described previously, the width of the upper region 173 of the gate metal can be reduced to achieve a smaller gate to drain capacitance. The current spreading is not affected to the help of the PVD formed metal layer 154. This is because the PVD metal layer 154 has lower resistance and silicide 152 as high resistance. Only relying on silicide to lead the current from a place without source/drain metal is a path of high resistance. After depositing the PVD metal layer 154, the entire silicide 152 can easily spread current to the PVD metal layer 154 having low resistance. After current flows into the PVD metal layer 154 from the silicide 152, it is easier to flow into the metal layer 164 deposited on the metal layer 154 due to low resistance.

A further benefit of the process and structures described herein, dummy source/drain contacts can be omitted. Dummy source/drain contacts may be used in some solutions for pattern uniformity. However, here the dummy source/drain contacts may be omitted due to both the PVD metal layer 154 and the silicide 152 as described herein.

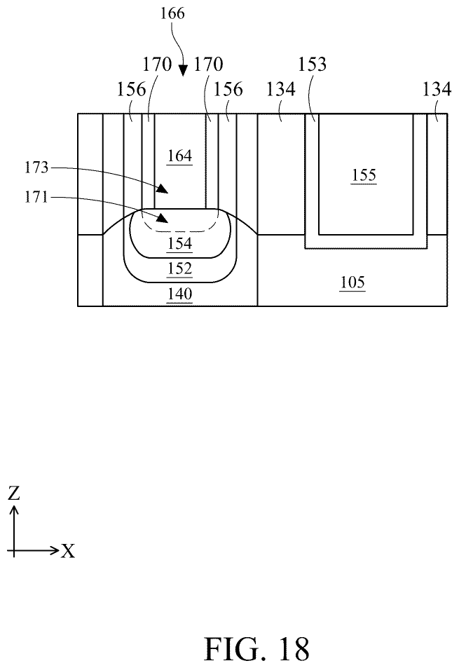

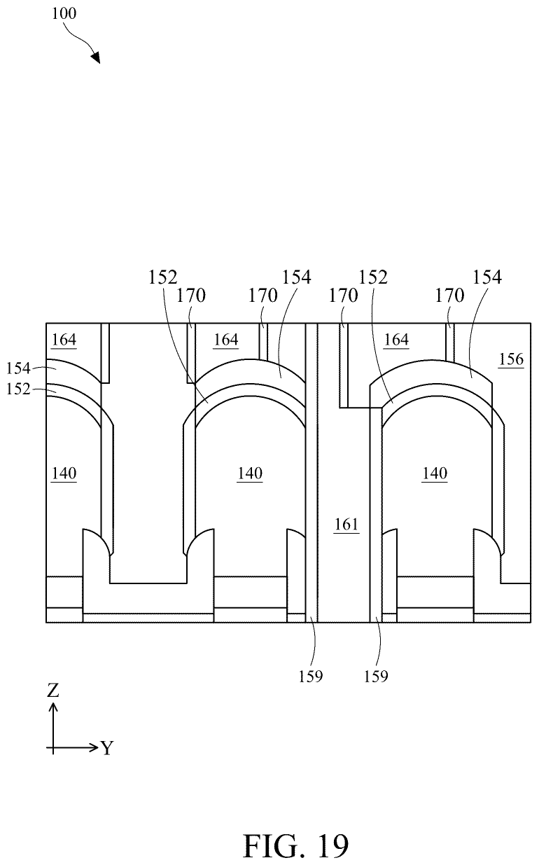

FIG. 18 is a cross-sectional view of the integrated circuit 100 of FIG. 15 taken along cut lines 16, in accordance with some embodiments. More particularly, FIG. 19 illustrates an embodiment in which an additional dielectric liner layer 170 has been formed in the source/drain contacts trench 162 prior to deposition of the metal layer 164. Accordingly, the dielectric liner layer 170 can be deposited at the stage of processing shown in FIG. 13. The dielectric liner layer 170 can include SiOCN, SiOC, SiON, SiN, or other suitable dielectric materials. The dielectric liner layer 170 can be deposited by PVD, ALD, CVD, or other suitable dielectric processes. The dielectric liner layer can have a width between 0.2 nm and 2 nm, though other dimensions can be utilized without departing from the scope of the present disclosure.

The dielectric liner layer 170 can serve to further reduce the width of the upper region 173. This further reduces the gate to drain capacitance. Furthermore, this can help enhance the adhesion between the metal layers 154 and 164.

FIG. 19 is a cross-sectional view of the integrated circuit 100 of FIG. 15 taken along cut lines 17, in accordance with some embodiments. FIG. 19 further illustrates the dielectric liner layer 170 present on sidewalls of the metal layer 164.

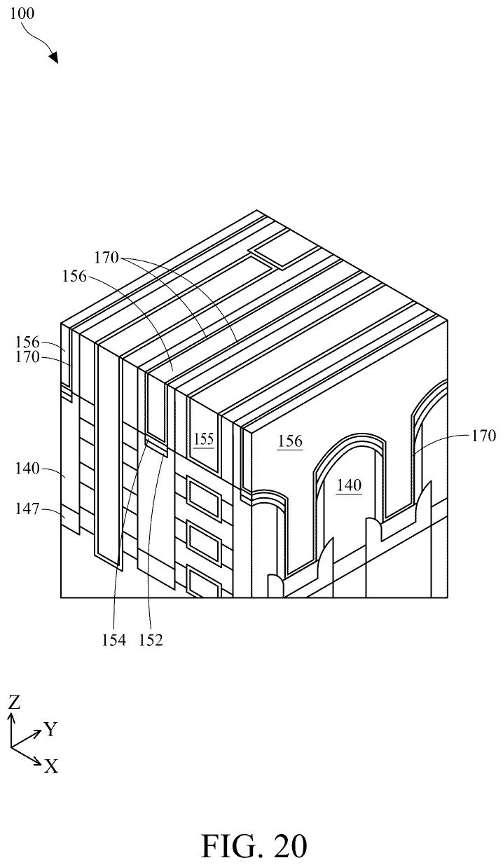

FIG. 20 is a perspective view of an integrated circuit 100, in accordance with some embodiments. The integrated circuit 100 corresponds to a stage of processing shown in FIG. 13, except that an additional liner layer 170 has been conformally deposited prior to formation of the dielectric layer 156. The dielectric liner layer 170 may correspond to the dielectric liner layer 170 of FIGS. 18 and 19. Accordingly, the dielectric liner layer 170 is deposited after formation of the metal layer 154 and prior to deposition of the dielectric layer 156.

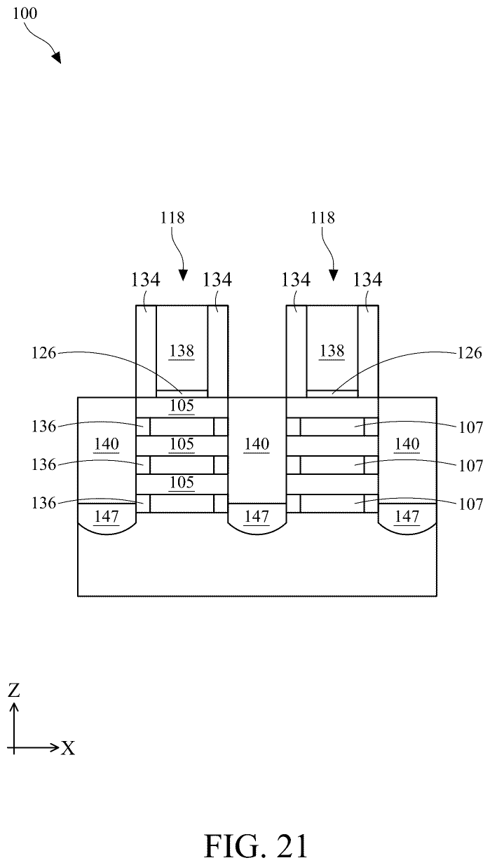

FIG. 21 is a cross-sectional view of an integrated circuit 100, in accordance with some embodiments. The stage of processing shown in FIG. 21 corresponds to the stage of processing shown in FIG. 6. FIG. 21 illustrates the bottom isolation structures 147.

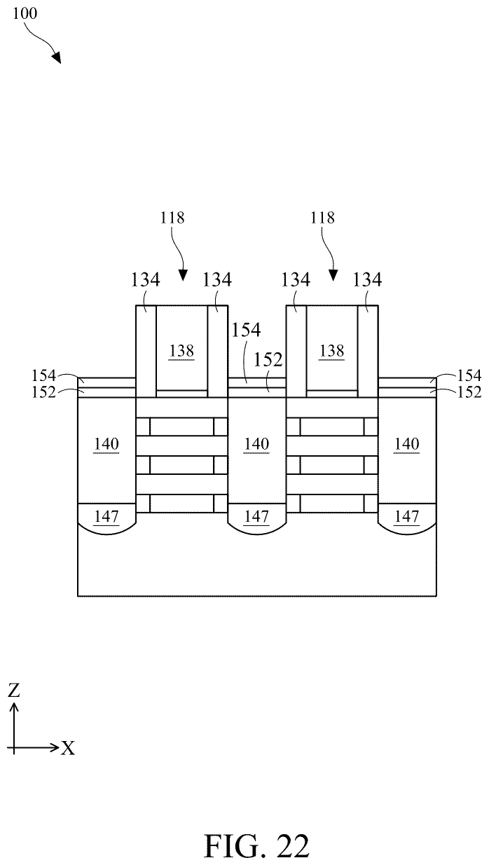

FIG. 22 is a cross-sectional view of the integrated circuit 100 of FIG. 21 at a further stage of processing, in accordance with some embodiments. In particular, a P-type dopant implantation processes been performed for embodiments in which the transistors are PMOS transistors. The silicide 152 is then formed, on the source/drain regions 140, as described previously. The metal layer 154 is then formed on the silicide layer 152, as described previously. The silicide 152 and the metal layer 14 are formed prior to formation of the dielectric layers 144 and 146.

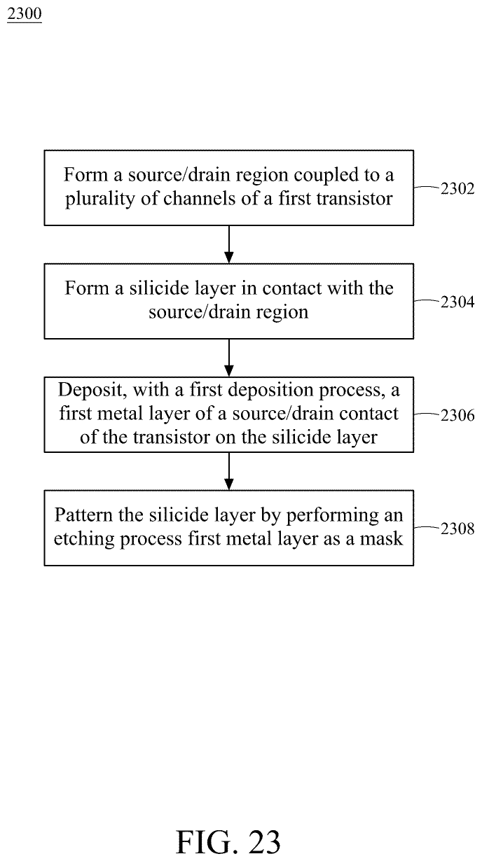

FIG. 23 is a flow diagram of a method 2300 for forming an integrated circuit, in accordance with some embodiments. The method 2300 can utilize the structures, processes, and systems described in relation to FIGS. 1-22. At 2302, the method 2300 includes forming a source/drain region coupled to a plurality of channels of a first transistor. One example of a source/drain region is the source/drain region 140 of FIG. 8. One example of channels are the channels 105 of FIG. 8. At 2302, the method 2300 includes forming a silicide layer in contact with the source/drain region. One example of a silicide layer is the silicide layer 152 of FIG. 11. At 2306, the method 2300 includes depositing, with a first deposition process, a first metal layer of a source/drain contact of the transistor on the silicide layer. One example of a first metal layer is the first metal layer 154 of FIG. 12. At 2308, the method 2300 includes patterning the silicide layer by performing an etching process using the first metal layer as a mask.

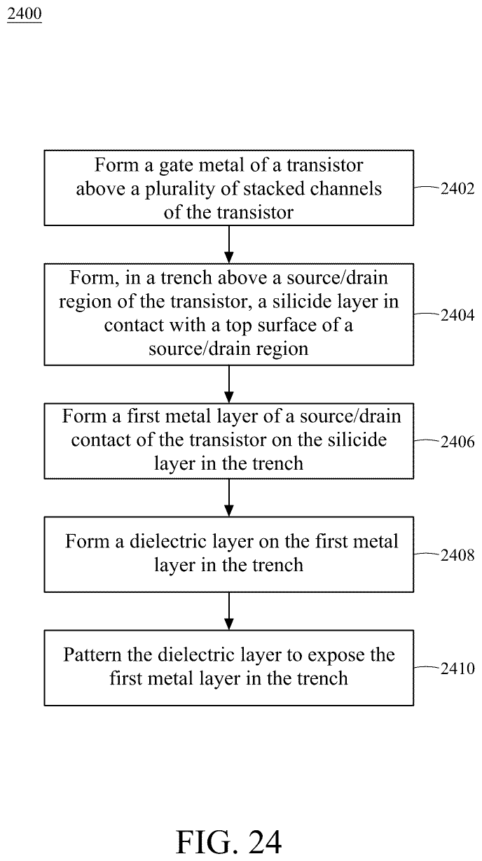

FIG. 24 is a flow diagram of a method 2400 for forming an integrated circuit, in accordance with some embodiments. The method 2400 can utilize the structures, processes, and systems described in relation to FIGS. 1-22. At 2402, the method 2400 includes forming a gate metal of a transistor above a plurality of stacked channels of the transistor. One example of a gate metal is the gate metal 150 of FIG. 8. One example of stacked channels are the channels 105 of FIG. 8. At 2404, the method 2400 includes forming, in a trench above a source/drain region of the transistor, a silicide layer in contact with a top surface of a source/drain region. One example of a source/drain region is the source/drain region 140 of FIG. 8. One example of a silicide layer is the silicide layer 152 of FIG. 11. At 2406, the method 2400 includes forming a first metal layer of a source/drain contact of the transistor on the silicide layer in the trench. One example of a first metal layer is the first metal layer 154 of FIG. 12. At 2408, the method 2400 includes forming a dielectric layer on the first metal layer in the trench. One example of a dielectric layer is the dielectric layer 156 of FIG. 13. At 2410, the method 2400 includes patterning the dielectric layer to expose the first metal layer in the trench.

Embodiments of the present disclosure provide an integrated circuit including transistors having source/drain contacts with improved electrical characteristics. Silicide is provided between the semiconductor source/drain regions and source/drain contacts. A first source/drain contact metal is formed on the silicide and the silicide is patterned in the presence of the first source/drain contact metal. A second source/drain contact metal is then deposited on the first source/drain contact metal. The silicide has a relatively large area in order to help reduce the resistance between the source/drain contacts and the source/drain regions. Because the resistance is reduced by increasing silicide area, the critical dimension of the source/drain contact can be decreased. This further results in increased scalability of source/drain contacts and a decrease in the capacitance between the source/drain contacts and gate metals. This results in transistors having improved processing speeds, reduced power consumption, and reduced area consumption. This further results in better functioning integrated circuits.

In some embodiments, a method includes forming a source/drain region coupled to a plurality of channels of a first transistor and forming a silicide layer in contact with the source/drain region. The method includes depositing, with a first deposition process, a first metal layer of a source/drain contact of the transistor on the silicide layer and patterning the silicide layer by performing an etching process using the first metal layer as a mask.

In some embodiments, an integrated circuit includes a transistor. The transistor includes a plurality of stacked channels, a source/drain region in contact with each of the stacked channels and including a concave top surface, a silicide layer on a top surface of the source/drain region, and an etch stop layer on the top surface of the source/drain region. The transistor includes a first dielectric layer on a sidewall of the etch stop layer and a metal source/drain contact including a lower region in contact with the silicide below the first dielectric layer and an upper region laterally adjacent to a sidewall of the first dielectric layer.

In some embodiments, a method includes forming a gate metal of a transistor above a plurality of stacked channels of the transistor and forming, in a trench above a source/drain region of the transistor, a silicide layer in contact with a top surface of a source/drain region. The method includes forming a first metal layer of a source/drain contact of the transistor on the silicide layer in the trench, forming a dielectric layer on the first metal layer in the trench, and patterning the dielectric layer to expose the first metal layer in the trench.

The gate all around (GAA) transistor structures discussed herein may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a source/drain region coupled to a plurality of channels of a transistor;
forming a silicide layer in contact with the source/drain region;
depositing, with a first deposition process, a first metal layer of a source/drain contact of the transistor on the silicide layer; and
patterning the silicide layer by performing an etching process using the first metal layer as a mask.

2. The method of claim 1, comprising depositing a second metal layer of the source/drain contact on the first metal layer with a second deposition process after the etching process.

3. The method of claim 1, comprising:
forming a gate metal above the plurality of channels adjacent to a gate spacer layer;
forming a first dielectric layer on sidewalls of a gate spacer layer and on a top surface of the source/drain region;
forming a second dielectric layer on the first dielectric layer;
forming a hard mask layer on the gate metal and on the first dielectric layer, the hard mask layer exposing the second dielectric layer;
exposing the top surface of the source/drain region by etching the second dielectric layer and a bottom portion of the first dielectric layer in a presence of the hard mask layer; and
forming the silicide layer on the top surface of the source/drain region after etching first and second dielectric layer.

4. The method of claim 3, comprising forming the hard mask layer by selectively growing the hard mask layer on the gate metal, the gate spacer layer, and the first dielectric layer.

5. The method of claim 4, comprising depositing the first metal layer on the silicide layer above the source/drain region and above the gate metal with a physical vapor deposition process that does not deposit the gate metal on vertical surfaces.

6. The method of claim 3, comprising:
removing the hard mask layer after depositing the first metal layer;
depositing a third dielectric layer on sidewalls of the first dielectric layer above the first metal layer; and
depositing a second metal layer on sidewalls of the third dielectric layer above the first metal layer.

7. The method of claim 6, comprising:
exposing the first metal layer by forming a trench in the third dielectric layer; and
depositing the second metal layer in the trench on the first metal layer.

8. The method of claim 3, comprising:
removing the hard mask layer after depositing the first metal layer;
depositing a third dielectric layer on sidewalls of the first dielectric layer above the first metal layer;
depositing a fourth dielectric layer on sidewalls of the third dielectric layer above the first metal layer; and
depositing the second metal layer on sidewalls of the fourth dielectric layer above the first metal layer.

9. The method of claim 2, wherein the first metal layer and the second metal layer are a same metal.

10. The method of claim 2, wherein the second metal layer is laterally offset with respect to the first metal layer.

11. An integrated circuit, comprising:
a transistor including:
a plurality of stacked channels;
a source/drain region in contact with each of the stacked channels and including a concave top surface;
a silicide layer on a top surface of the source/drain region;
an etch stop layer on the top surface of the source/drain region;
a first dielectric layer on a sidewall of the etch stop layer; and
a metal source/drain contact including a lower region in contact with the silicide layer below the first dielectric layer and an upper region laterally adjacent to a sidewall of the first dielectric layer.

12. The integrated circuit of claim 11, wherein the transistor includes a second dielectric layer on a sidewall of the first dielectric layer directly above the lower region, wherein the upper region is in direct contact with a sidewall of the second dielectric layer directly above the lower region.

13. The integrated circuit of claim 11, wherein the lower region is wider than the upper region.

14. The integrated circuit of claim 11, wherein the transistor includes a gate metal above the stacked channels, wherein the lower region is laterally closer to the gate metal than is the upper region.

15. The integrated circuit of claim 11, wherein the lower region has curved sidewalls, wherein the upper region has straight sidewalls.

16. The integrated circuit of claim 11, wherein the upper region is laterally offset with respect to the lower region.

17. The integrated circuit of claim 11, wherein the lower region and the upper region are substantially an L-shape.

18. A method, comprising:
forming a gate metal of a transistor above a plurality of stacked channels of the transistor;
forming, in a trench above a source/drain region of the transistor, a silicide layer in contact with a top surface of a source/drain region;
forming a first metal layer of a source/drain contact of the transistor on the silicide layer in the trench;
forming a dielectric layer on the first metal layer in the trench; and
patterning the dielectric layer to expose the first metal layer in the trench.

19. The method of claim 18, comprising, after patterning the dielectric layer, forming a second metal layer of the source/drain contact in contact with the first metal layer and in contact with a sidewall of the dielectric layer in the trench.

20. The method of claim 19, wherein the first metal layer is laterally closer to the gate metal than is the second metal layer.
